(19) United States
(12) Patent Application Publication
(10) Pub. No.: US 2026/0343936 A1
(43) Pub. Date: Oct. 29, 2026

(54) METAL-GATE FDSOI DEVICE AND MANUFACTURING METHOD THEREOF

(71) Applicant: Shanghai Huali Integrated Circuit Corporation, Shanghai (CN)

(72) Inventors: Zhi TIAN, Shanghai (CN); Yurong CAO, Shanghai (CN); Haoyu CHEN, Shanghai (CN); Hua SHAO, Shanghai (CN)

(73) Assignee: Shanghai Huali Integrated Circuit Corporation, Shanghai (CN)

(21) Appl. No.: 19/635,832

(22) Filed: Apr. 1, 2026

(30) Foreign Application Priority Data
Apr. 28, 2025 (CN) 2025105546621

(51) Int. Cl. H10D 30/63; H10D 64/23; H10D 86/00; H10D 86/01

(52) U.S. Cl. CPC H10D 30/637; H10D 64/259; H10D 86/01; H10D 86/201

(57) ABSTRACT

A metal-gate FDSOI device and manufacturing method are disclosed. The method includes, connecting the metal gate structures and the HiR layer in parallel, which reduces the gate resistance, thereby enhancing the improvement of the device's maximum oscillation frequency (Fmax) as achieved by reduced channel length, and boosting RF performance. Plus, enlarging the HiR layer helps reduce the HiR resistance, further lowering the overall parallel resistance and improving device performance. In addition, forming source and drain elevation layers above the source and drain regions, and forming cone-shaped source and drain metal layers. Aligning the cone-shaped source and drain metal layers to the source and drain elevation layers, so the cone-shaped source and drain metal layers are electrically connected to source and drain through the source and drain elevation layers respectively. Moreover, no additional photo mask is required, making this approach fully compatible with current manufacturing processes.

### FIELD OF THE INVENTION

The present disclosure relates to the field of semiconductor technology, in particular to a metal-gate FDSOI device and a manufacturing method thereof.

### BACKGROUND OF THE INVENTION

Fully-Depleted Silicon-On-Insulator (FDSOI) devices are fabricated with an extremely thin semiconductor film as the transistor channel on the buried oxide layer. Because the channel is very thin, there is no need for a doping process in the channel, and the depletion layer fills the entire channel region, resulting in a fully depleted transistor.

The buried oxide layer of FDSOI devices can reduce the parasitic capacitance between the source and drain, and effectively suppress the flow of electrons from the source to the drain, thereby significantly reducing the leakage current that leads to performance degradation. Additionally, FDSOI devices have many other unique advantages, such as back-bias capability, excellent transistor matching characteristics, the ability to use low supply voltages near the threshold, ultra-low sensitivity to radiation, and very high intrinsic transistor operating speeds. These advantages enable them to operate in millimeter-wave applications. For radio frequency (RF) performance, parameters such as the cutoff frequency (Ft) and the maximum oscillation frequency (Fmax) are typically of concern, with many influencing factors including transistor transconductance, inversion layer capacitance, and gate resistance. To achieve higher transconductance and smaller inversion layer capacitance, a smaller gate length is usually used in the design, which can improve Ft. Moreover, since the gate in RF devices acts as a low-resistance conductor, reducing the gate resistance is desirable to enhance Fmax.

FIG. 1 is a schematic showing single-ended leading out of metal gates, where each metal gate 01 is flanked by a source region 02 and a drain region 03, and a metal lead-out layer 04 is connected to one end of each metal gate 01. FIG. 2 is a schematic showing double-ended leading out of metal gates, where a metal lead-out layer 04 is connected to both ends of each metal gate 01, which can reduce the gate resistance. Taking four metal gates as an example, adopting the double-ended metal gates can reduce the total gate resistance to ¼ of its original value before modification, and combined with the reduction in gate length, this can improve Fmax. Refer to FIG. 3, which shows relationships between Ft/Fmax and the channel length of the device (N-type) with double-ended metal gate, where both Ft and Fmax increase as the channel length (i.e., gate length) decreases, with Fmax increasing at a slower rate. Although connecting both ends of the metal gates can reduce gate resistance and reducing the gate length can also lower gate resistance, thereby improving Fmax, the improvement in Fmax is limited and cannot meet the needs of high-performance RF applications. Increasing the gate thickness can further reduce resistance, but this gate thickness increase would lead to an increase in gate coupling capacitance, which hinders the enhancement of Fmax.

### SUMMARY OF THE INVENTION

. A first aspect of the present disclosure provides a metal-gate FDSOI device, including:
an SOI substrate, wherein the SOI substrate includes a base layer, a buried insulating layer, and a semiconductor layer;
a metal gate structure, over the SOI substrate, wherein an area of the semiconductor layer covered by the metal gate structure is configured to be a channel region, and areas of the semiconductor layer on two sides of the channel region are respectively configured to be a source region and a drain region;
an insulating layer, over the SOI substrate, covering the metal gate structure;
a HiR layer, over the insulating layer, wherein a first direction points from the source region toward the drain region and perpendicular to the metal gate end-to-end length, a length of the HiR layer along a second direction perpendicular to the first direction is shorter than the channel length of the metal gate structure, wherein the second direction is parallel to the top surface of the SOI substrate;
a dielectric layer, over the insulating layer and covering the HiR layer; wherein along the first direction, two ends of the HiR layer are provided with shared contact holes, wherein the shared contact holes penetrate the HiR layer and the insulating layer, and partially expose the metal gate structure; and
conductive interconnection structures, formed by filling the shared contact holes with a conductive material, and wherein the conductive interconnection structures connect the HiR layer and the metal gate structure in parallel.

A second aspect of the present disclosure provides a manufacturing method of a metal-gate FDSOI device, including:
providing an SOI substrate, wherein the SOI substrate includes a base layer, a buried insulating layer, and a semiconductor layer;
forming a metal gate structure over the SOI substrate, wherein an area of the semiconductor layer covered by the metal gate structure is configured to be a channel region, and areas of the semiconductor layer on two sides of the channel region are respectively configured to be a source region and a drain region;
forming an insulating layer over the SOI substrate, wherein the insulating layer covers the metal gate structure;
forming a HiR layer over the insulating layer, wherein a first direction points from the source region toward the drain region and is perpendicular to the metal gate end-to-end length, a length of the HiR layer along a second direction perpendicular to the first direction is shorter than that of the metal gate structure, wherein the second direction is parallel to the top surface of the SOI substrate;
forming a dielectric layer over the insulating layer and covering the HiR layer, and forming shared contact holes on two ends of the HiR layer along the first direction, wherein the shared contact holes penetrate the HiR layer and the insulating layer, and partially expose the metal gate structure; and
filling the shared contact holes with conductive material to form conductive interconnection structures, wherein the conductive interconnection structures connect the HiR layer and the metal gate structure in parallel.

In the presently disclosed metal-gate FDSOI device and manufacturing method thereof, the metal gate structures and the HiR layer are connected in parallel. This leverages the characteristics of parallel resistors to reduce the gate resistance, thereby enhancing the already improved device's maximum oscillation frequency (Fmax) as achieved by reducing channel length, and boosting RF performance. Additionally, enlarging the HiR layer helps to reduce the HiR resistance, further lowering the overall parallel resistance and improving device performance. Moreover, no additional photomask is required by this process, making this approach fully compatible with existing metal gate manufacturing processes.

### BRIEF DESCRIPTION OF DRAWINGS

FIG. 1 is a schematics showing single-ended leading out of metal gates.

FIG. 2 is a schematics showing double-ended leading out of metal gates.

FIG. 3 shows data plots of variations of Ft and Fmax versus metal gate channel length for an N-type device with double-ended leading out of its metal gates.

FIG. 4 shows a top view of a metal-gate FDSOI device according to Embodiment 1 of the present disclosure.

FIG. 5 shows a partially enlarged view of the dashed region in FIG. 4.

FIG. 6 shows a cross-sectional view with its cutting plane passing through Line AA′ in FIG. 5.

FIG. 7 shows a cross-sectional view with its cutting plane passing through Line BB′ in FIG. 5.

FIG. 8 is the data chart illustrating the correlation between HiR layer width and metal gate sheet resistance in Embodiment 1 of the present disclosure.

FIG. 9 is a schematic structural diagram showing width expansion of the HiR layer between the source elevation layer and the drain elevation layer according to Embodiment 1 of the present disclosure.

FIG. 10 is a schematic structural diagram showing no width expansion of the HiR layer without the source elevation layer and drain elevation layer as compared to FIG. 9.

FIG. 11 shows a flowchart illustrating a method for manufacturing a metal-gate FDSOI device according to Embodiment 2 of the present disclosure.

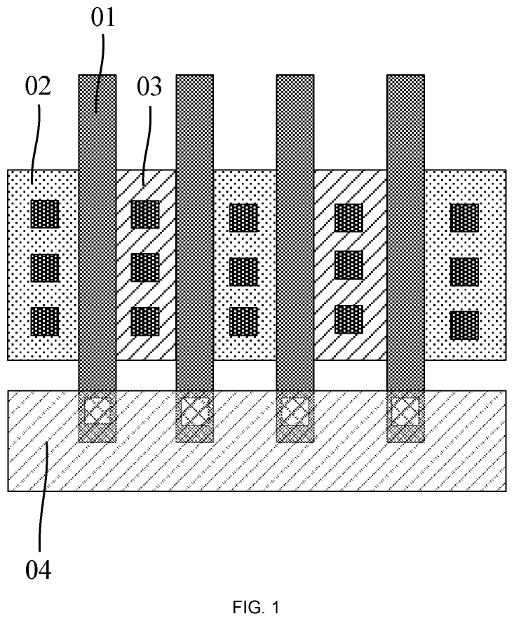

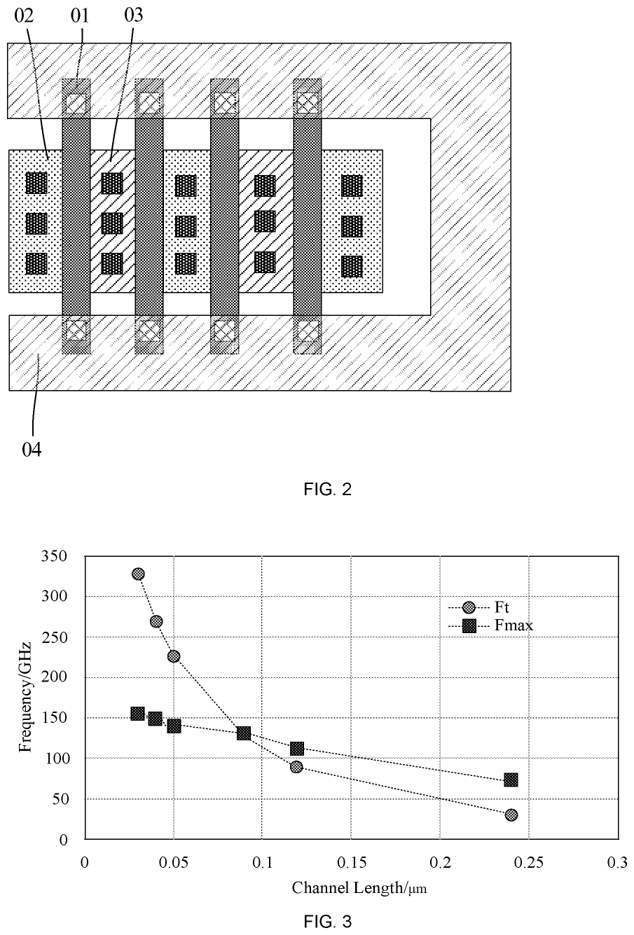

### REFERENCE NUMERALS

01 Metal gate
02 Source region
03 Drain region
04 Metal lead-out layer
1 SOI substrate
100 base layer
101 buried insulating layer
102 semiconductor layer
2 Metal gate structure
3 Channel region
4 Source region
5 Drain region
6 insulating layer
7 HiR layer
8 Dielectric layer
9 conductive interconnection structures
10 Source metal layer
11 Drain metal layer
12 Source elevation layer
13 Drain elevation layer
14 Metal lead-out layer
S1~S6 Various steps

### DETAILED DESCRIPTION

The embodiments of the present disclosure will be described below. Those skilled can easily understand advantages and effects of the present disclosure according to contents disclosed by the specification. The present disclosure can also be implemented or applied through other different exemplary embodiments. Various modifications or changes can also be made to all details in the specification based on different points of view and applications without departing from the spirit of the present disclosure.

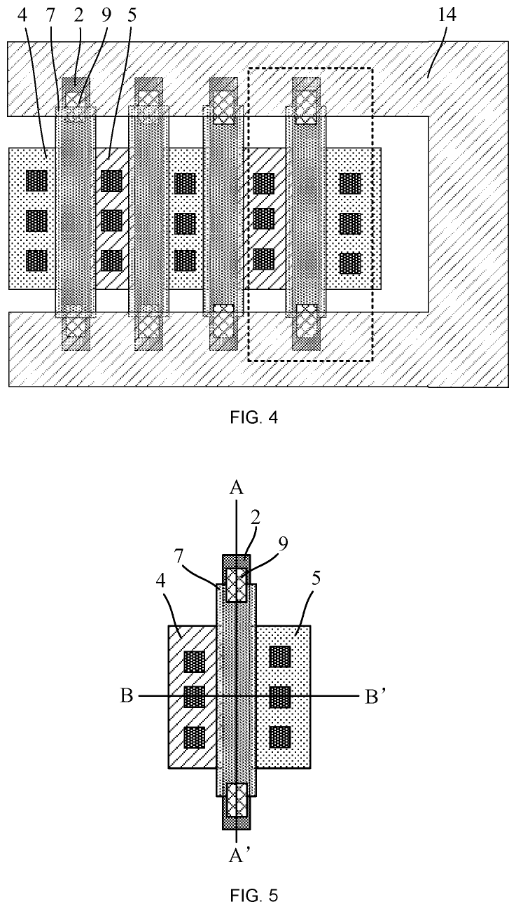

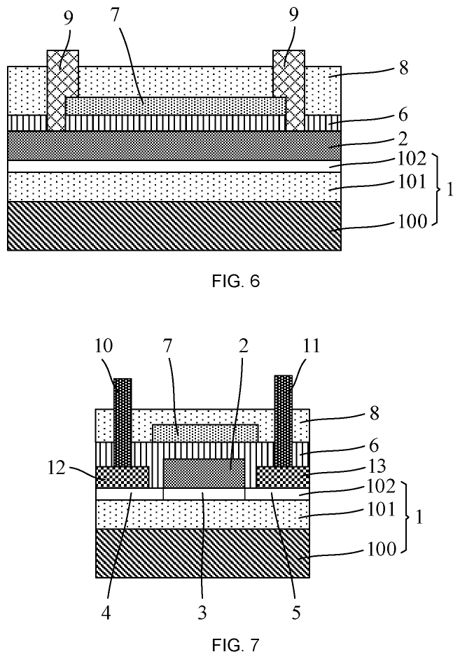

Refer to FIGS. 4-11. It should be noted that the drawings provided in this disclosure only illustrate the basic concept of the present disclosure in a schematic way, so the drawings only show the components closely related to the present disclosure. The drawings are not necessarily drawn according to the number, shape and size of the components in actual implementation; during the actual implementation, the type, quantity and proportion of each component can be changed as needed, and the components' layout may also be more complicated.

### Embodiment 1

Embodiment 1 provides a metal-gate FDSOI device, as shown in FIGS. 4 to 7, the metal-gate FDSOI device includes an SOI substrate 1, a metal gate structure 2, an insulating layer 6, a HiR layer 7, a dielectric layer 8, and conductive interconnection structures 9, wherein the SOI substrate 1 includes a base layer 100, a buried insulating layer 101, and a semiconductor layer 102. The metal gate structure 2 is over the SOI substrate 1, and an area of the semiconductor layer 102 covered by the metal gate structure 2 is configured to be a channel region 3, and areas of the semiconductor layer 102 on two sides of the channel region 3 are respectively configured to be a source region 4 and a drain region 5. The insulating layer 6 is over the SOI substrate 1 and covers the metal gate structure 2. The HiR layer 7 is over the insulating layer 6. A first direction points from the source region 4 toward the drain region 5 and is perpendicular to the metal gate end-to-end length. A length of the HiR layer 7 along a second direction perpendicular to the first direction is shorter than that of the metal gate structure 2, wherein the second direction is parallel to the top surface of the SOI substrate 1. The dielectric layer 8 is over the insulating layer 6 and covers the HiR layer 7. Along the first direction, two ends of the HiR layer 7 are provided with shared contact holes, wherein the shared contact holes penetrate the HiR layer 7 and the insulating layer 6, and partially expose the metal gate structure 2. The conductive interconnection structures 9 fill the shared contact holes, and the conductive interconnection structures 9 connect the HiR layer 7 and the metal gate structure 2 in parallel.

As an example, in the SOI substrate 1, the base layer 100 is a silicon layer, the buried insulating layer 101 is a silicon oxide layer (BOX), and the semiconductor layer 102 is a silicon layer.

As an example, the metal gate structure 2 includes a gate dielectric layer and a gate metal layer stacked together, where the gate dielectric layer may be a high-k dielectric layer such as an HfO₂ layer, and the gate metal layer may be an Al layer.

As an example, the insulating layer 6 is used to insulate the metal gate structure 2 from the HiR layer 7. As an example, the insulating layer 6 is made of silicon oxide.

As an example, the HiR layer 7 is a high-resistance layer. As an example, the HiR layer 7 is made of a TiN layer.

As an example, the dielectric layer 8 is an interlayer dielectric layer. As an example, the dielectric layer 8 is a silicon oxide layer.

As an example, the shared contact holes are distributed along the second direction, and positioned at two ends of the HiR layer 7. The shared contact holes penetrate the dielectric layer 8, the HiR layer 7, and the insulating layer 6. The shared contact holes partially expose the metal gate structure 2. A metal layer is filled into the shared contact holes to form the conductive interconnection structures 9, which electrically connect the HiR layer 7 and the metal gate structure 2 in parallel.

As an example, by connecting the HiR layer 7 and the metal gate structure 2 in parallel, characteristics of parallel resistance are utilized to reduce the gate resistance.

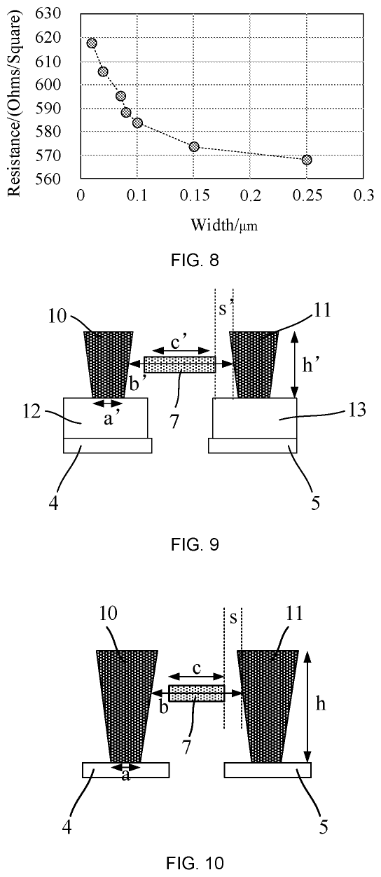

As an example, refer to FIG. 8, it can be seen that the width of the HiR layer 7 is inversely proportional to its unit square resistance. As an example, the width of the HiR layer 7 is greater than the width of the metal gate structure 2 along the first direction. By increasing the width of the HiR layer 7, its resistance is reduced, thereby lowering the parallel resistance.

As an example, the structure further includes a coned source contact hole and a coned drain contact hole. The source contact hole penetrates the dielectric layer 8 and the insulating layer 6, and the source metal layer 10 fills the source contact hole and is electrically connected to the source region 4. The drain contact hole penetrates the dielectric layer 8 and the insulating layer 6, and the drain metal layer 11 fills the drain contact hole and is electrically connected to the drain region 5.

As an example, a source elevation layer 12 is formed between the source region 4 and the insulating layer 6, and the source metal layer 10 is electrically connected to the source region 4 through the source elevation layer 12; As an example, a drain elevation layer 13 is formed between the drain region 5 and the insulating layer 6, and the drain metal layer 11 is electrically connected to the drain region 5 through the drain elevation layer 13, wherein the source elevation layer 12 has the same doping type as the source region 4, and the drain elevation layer 13 has the same doping type as the drain region 5.

As an example, by including the source elevation layer 12 and the drain elevation layer 13, the contact resistance between the source and drain can be reduced. Due to the thinness of the semiconductor layer 102 in the SOI substrate 1, it is not possible to form low-resistance refractory silicide. By setting up the source elevation layer 12 and the drain elevation layer 13, the increased thickness allows for the formation of a low-resistance refractory silicide layer, thereby reducing the contact resistance of the source and drain. In addition, during the contact hole forming, the shape of the holes usually is coned which has a smaller diameter at the bottom and gets wider with the height of the interconnection structure. This shape is generated naturally in forming process. By incorporating the source elevation layer 12 and the drain elevation layer 13, the bottom of hole structure is raised to the top level of the elevation layer, but the position of the HiR layer is not changed, therefore the width of the HiR layer 7 can be further increased into the narrower part of the conductive structure which has a smaller diameter. Without the elevated layers in FIG. 10, the HiR layer 7 is aligned to the “fatter” part of the conductive structure which has a larger diameter. As illustrated in FIGS. 9 and 10, when the diameter at the bottom of the coned contact holes remains the same (a=a′), the inclusion of the source elevation layer 12 and the drain elevation layer 13 can decrease the height of the contact holes (h′<h), thereby increasing the distance between the contact holes (b′>b) (taking the average distance or median distance as an example, with the contact holes assuming a truncated cone shape naturally by the forming process). At this time, maintaining the same distance from the contact holes to the HiR layer 7 (s=s′) enables an increase in the width of the HiR layer 7 (c′>c), thereby further reducing the parallel resistance.

As an example, the structure further includes a metal lead-out layer 14 connected to two ends of the metal gate structure 2. By employing double-ended leading out of the metal gate structure 2, the gate resistance is thereby reduced.

As an example, refer to Table 1 below: when the channel length (Length) of the device is reduced, the transconductance (Gm) increases, and the inversion layer capacitance (Cinv) decreases. When the gate and the HiR layer are not connected in parallel, the reduction in gate resistance (Rgate) is limited, and the improvements in cutoff frequency (Ft) and maximum oscillation frequency (Fmax) are moderate. In contrast, when the HiR layer and the metal gate structure are connected in parallel, the gate resistance (Rgate) decreases more significantly (i.e., a greater reduction in Rgate), enabling substantial enhancements in Ft and Fmax, thereby meeting high-performance requirements.

TABLE 1

| Conditions | Length | Gm | Cinv | Rgate | Ft | Fmax |
|---|---|---|---|---|---|---|
| Gate and | decrease | increase | decrease | decrease | increase | increase |
| HiR layer not | | | | | | |
| connected in | | | | | | |
| parallel | | | | | | |
| Gate and | decrease | increase | decrease | decrease+ | increase+ | increase+ |
| HiR layer | | | | | | |
| connected in | | | | | | |
| parallel | | | | | | |

Refer to Table 2 below. Taking an N-type device as an example, when the HiR layer and the gate are not connected in parallel, the metal gate (MG) with a width of 0.1 μm and an effective resistance length of 2 μm exhibits a resistance value of 2000 ohm, while the MG with a width of 0.02 μm and an effective resistance length of 2 μm has a resistance value of 812 ohm. When the HiR layer and the gate are connected in parallel: for the MG (0.1 μm width, 2 μm effective resistance length) combined with a HiR layer (0.1 μm width, 2 μm effective resistance length), the estimated parallel resistance value is 1729 ohm, representing a reduction of approximately 13%; for the MG (0.02 μm width, 2 μm effective resistance length) combined with a HiR layer (0.1 μm width, 2 μm effective resistance length), the estimated parallel resistance value is 760 ohm, corresponding to a reduction of approximately 6%.

In can be seen that, by connecting the metal gate and HiR layer in parallel, the gate resistance is reduced, thereby improving the device's radio-frequency (RF) performance.

TABLE 2

| | Width | Effective resistance | Resistance | |
|---|---|---|---|---|
| Conditions | (μm) | length (μm) | value (ohm) | |
| HiR resistance | 0.1 | 2 | 12800 | |
| Metal gate | 0.1 | 2 | 2000 | |
| resistance | 0.02 | 2 | 812 | |
| (N-type) | | | | |
| Estimated | 0.1 (MG)/0.1 | 2 | 1729 | (−13%) |
| parallel | (HiR) | | | |
| resistance | 0.02 (MG)/ | 2 | 760 | (−6%) |

| | |
|---|---|
| (N-type) | 0.1(HiR) |

In the presently disclosed metal-gate FDSOI device and manufacturing method thereof, the metal gate structures and the HiR layer are connected in parallel. This leverages characteristics of parallel resistors to reduce the gate resistance, thereby enhancing the improvement of the device's maximum oscillation frequency as achieved by reduced channel length, and boosting RF performance. Additionally, enlarging the HiR layer helps reduce the HiR resistance, further lowering the overall parallel resistance and improving device performance.

### Embodiment 2

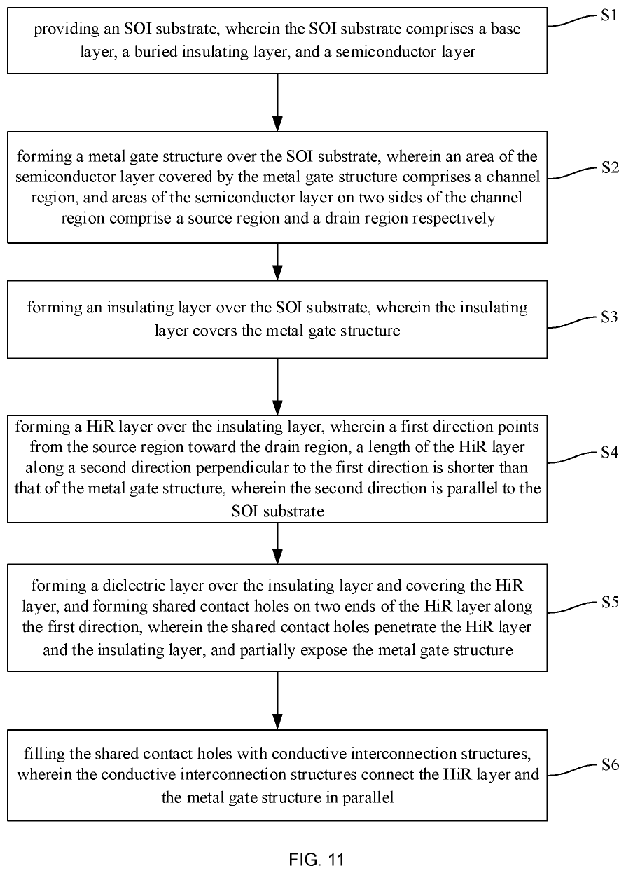

Embodiment 2 provides a manufacturing method of a metal-gate FDSOI device, as shown in FIG. 11, and the method includes steps S1-S6.
S1: providing an SOI substrate, wherein the SOI substrate includes a base layer, a buried insulating layer, and a semiconductor layer;
S2: forming a metal gate structure over the SOI substrate, wherein an area of the semiconductor layer covered by the metal gate structure is configured to be a channel region, and areas of the semiconductor layer on two sides of the channel region are respectively configured to be a source region and a drain region;
S3: forming an insulating layer over the SOI substrate, wherein the insulating layer covers the metal gate structure;
S4: forming a HiR layer over the insulating layer, wherein a first direction points from the source region toward the drain region and is perpendicular to the metal gate end-to-end length, a length of the HiR layer along a second direction perpendicular to the first direction is shorter than that of the metal gate structure, wherein the second direction is parallel to the top surface of the SOI substrate;
S5: forming a dielectric layer over the insulating layer and covering the HiR layer, and forming shared contact holes on two ends of the HiR layer along the first direction, wherein the shared contact holes penetrate the HiR layer and the insulating layer, and partially expose the metal gate structure; and
S6: filling the shared contact holes with conductive interconnection structures, wherein the conductive interconnection structures connect the HiR layer and the metal gate structure in parallel.

As an example, the method further includes: forming a source metal layer and a drain metal layer, wherein the source metal layer penetrates the dielectric layer and the insulating layer, and is electrically connected to the source region, wherein the drain metal layer penetrates the dielectric layer and the insulating layer, and is electrically connected to the drain region.

A first direction points from the source region toward the drain region and is perpendicular to the metal gate end-to-end length, a second direction is perpendicular to the first direction and parallel to the SOI substrate. As an example, along the first direction, the width of the HiR layer is greater than the width of the metal gate structure.

As an example, before forming the insulating layer, the method further includes: forming a source elevation layer and a drain elevation layer, wherein the source elevation layer is above the source region, and the drain elevation layer is above the drain region, wherein the source metal layer is electrically connected to the source region through the source elevation layer, and the drain metal layer is electrically connected to the drain region through the drain elevation layer.

As an example, the HiR layer is a TiN layer.

As an example, the method of Embodiment 2 is used to manufacture the metal-gate FDSOI device described in Embodiment 1. The content of Embodiment 1 may be fully referenced here.

In the presently disclosed metal-gate FDSOI device and manufacturing method thereof, the metal gate structures and the HiR layer are connected in parallel. This leverages characteristics of parallel resistors to reduce the gate resistance, thereby enhancing the improvement of the device's maximum oscillation frequency (Fmax) as achieved by reduced channel length, and boosting RF performance. Additionally, enlarging the HiR layer helps reduce the HiR resistance, further lowering the overall parallel resistance and improving device performance. Moreover, no additional mask is required, making this approach fully compatible with existing manufacturing processes. Therefore, the present disclosure effectively overcomes various shortcomings in the existing technology and has high industrial utilization value.

The above-mentioned embodiments are merely illustrative of the principle and effects of the present disclosure instead of restricting the scope of the present disclosure. Any person skilled in the art may modify or change the above embodiments without violating the principle of the present disclosure. Therefore, all equivalent modifications or changes made by those who have common knowledge in the art without departing from the spirit and technical concept disclosed by the present disclosure shall be still covered by the claims of the present disclosure.

1. A metal-gate Fully-Depleted Silicon-On-Insulator (FDSOI) device, comprising:
an SOI substrate, wherein the SOI substrate comprises a base layer, a buried insulating layer, and a semiconductor layer;
a metal gate structure, over the SOI substrate, wherein an area of the semiconductor layer covered by the metal gate structure comprises a channel region, and areas of the semiconductor layer on two sides of the channel region comprise a source region and a drain region respectively;
an insulating layer, over the SOI substrate, covering the metal gate structure;
a HiR layer, over the insulating layer, wherein a first direction points from the source region toward the drain region, a length of the HiR layer along a second direction, which is perpendicular to the first direction, is shorter than a length of the metal gate structure along the second direction, wherein the first direction and the second direction are both parallel to a top surface of the SOI substrate;
a dielectric layer, over the insulating layer and covering the HiR layer, wherein along the first direction, two ends of the HiR layer are provided with shared contact holes, wherein the shared contact holes penetrate the HiR layer and the insulating layer, and partially expose the metal gate structure; and
conductive interconnection structures, wherein the conductive interconnection structures fill the shared contact holes and connect the HiR layer and the metal gate structure in parallel.

2. The metal-gate FDSOI device according to claim 1, further comprising:
a coned source contact hole penetrating the dielectric layer and the insulating layer;
a source metal layer filling the coned source contact hole and electrically connected to the source region, forming a cone-shaped source metal layer;
a coned drain contact hole penetrating the dielectric layer and the insulating layer; and
a drain metal layer filling the coned drain contact hole and electrically connected to the drain region, forming a cone-shaped drain metal layer.

3. The metal-gate FDSOI device according to claim 2, further comprising:
a source elevation layer formed between the source region and the insulating layer, wherein the source elevation layer is aligned to a bottom of the cone-shaped source metal layer, and wherein the cone-shaped source metal layer is electrically connected to the source region through the source elevation layer; and
a drain elevation layer formed between the drain region and the insulating layer, wherein the drain elevation layer is aligned to a bottom of the cone-shaped drain metal layer, and wherein the cone-shaped drain metal layer is electrically connected to the drain region through the drain elevation layer.

4. The metal-gate FDSOI device according to claim 1, wherein a width of the HiR layer along the first direction is greater than a width of the metal gate structure.

5. The metal-gate FDSOI device according to claim 1, wherein the HiR layer is a TiN layer.

6. A manufacturing method of a metal-gate FDSOI device, comprising:
providing an SOI substrate, wherein the SOI substrate comprises a base layer, a buried insulating layer, and a semiconductor layer;
forming a metal gate structure over the SOI substrate, wherein an area of the semiconductor layer covered by the metal gate structure comprises a channel region, and areas of the semiconductor layer on two sides of the channel region comprise a source region and a drain region respectively;
forming an insulating layer over the SOI substrate, wherein the insulating layer covers the metal gate structure;
forming a HiR layer over the insulating layer, wherein a first direction points from the source region toward the drain region and is perpendicular to a metal gate end-to-end length, a length of the HiR layer along a second direction, which is perpendicular to the first direction, is shorter than a length of the metal gate structure along the second direction, wherein the first direction and the second direction are both parallel to a top surface of the SOI substrate;
forming a dielectric layer over the insulating layer and covering the HiR layer, and forming shared contact holes on two ends of the HiR layer along the first direction, wherein the shared contact holes penetrate the HiR layer and the insulating layer, and partially expose the metal gate structure; and
filling the shared contact holes with conductive interconnection structures, wherein the conductive interconnection structures connect the HiR layer and the metal gate structure in parallel.

7. The manufacturing method of the metal-gate FDSOI device according to claim 6, further comprising: forming a cone-shaped source metal layer and a cone-shaped drain metal layer, wherein the cone-shaped source metal layer penetrates the dielectric layer and the insulating layer, and is electrically connected to the source region, wherein the cone-shaped drain metal layer penetrates the dielectric layer and the insulating layer, and is electrically connected to the drain region.

8. The manufacturing method of the metal-gate FDSOI device according to claim 7, wherein before forming the insulating layer, the method further comprises: forming a source elevation layer and a drain elevation layer, wherein the source elevation layer is above the source region, and the drain elevation layer is above the drain region, wherein the source elevation layer is aligned to a bottom of the cone-shaped source metal layer, and wherein the cone-shaped source metal layer is electrically connected to the source region through the source elevation layer, and wherein the drain elevation layer is aligned to a bottom of the cone-shaped drain metal layer, and wherein the cone-shaped drain metal layer is electrically connected to the drain region through the drain elevation layer.

9. The manufacturing method of the metal-gate FDSOI device according to claim 6, wherein a width of the HiR layer along the first direction is greater than a width of the metal gate structure.

10. The manufacturing method of the metal-gate FDSOI device according to claim 6, wherein the HiR layer is a TiN layer.
